(19) United States
(12) Patent Application Publication
(10) Pub. No.: US 2007/0210421 A1
(43) Pub. Date: Sep. 13, 2007

(54) Semiconductor device fabricated using a carbon-containing film as a contact etch stop layer

(75) Inventors: Haowen Bu, Plano, TX (US); Anand T. Krishnan, Farmers Branch, TX (US); Ting Y. Tsui, Garland, TX (US); William W. Dostalik, Plano, TX (US); Rajesh Khamankar, Coppell, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/374,635

(22) Filed: Mar. 13, 2006

(51) Int. Cl. H01L 23/58; H01L 21/469

(52) U.S. Cl. 257/635; 257/642; 438/786; 438/778

(57) ABSTRACT

The invention provides, one aspect, a method of fabricating a semiconductor device. In one aspect, the method includes forming a carbide layer over a gate electrode and depositing a pre-metal dielectric layer over the carbide layer. The method provides a significant reduction in NBTI drift.

### TECHNICAL FIELD OF THE INVENTION

The invention is directed in general to a semiconductor device, and more specifically, to a semiconductor device fabricated using a carbon-containing film as a contact etch stop layer.

### BACKGROUND

High performance integrated circuits (ICs) have gained wide acceptance and utility in present day computing and telecommunications applications. Consumer demand has resulted in increasing functionality and speed of ICs, which is made possible by the constant shrinking of transistor feature sizes. These smaller transistors offer performance benefits, such as faster speed of operation and lower power, as well as lower cost. However, smaller features result in physical effects that must be compensated for in the processing of the IC device, and these compensating processes can introduce reliability concerns.

The reduction of transistor size demands reduction of transistor feature dimensions, such as the gate oxide thickness, Tₒₓ, and gate and channel length. Reduction of Tₒₓ is necessary to raise the capacitance of the gate as the transistor threshold voltage, Vₜ, is reduced as the transistor is scaled down. However, the channel length of state-of-the-art metal oxide semiconductor field effect transistors (MOSFETs) has been reduced to dimensions at which short channel effects have an increasing effect on transistor performance. This effect leads to a higher transistor Vₜ than would otherwise be necessary from scaling alone, and requires an increasing gate electric field strength, Eₒₓ, with each transistor technology generation.

Higher Eₒₓ results in greater stress on the gate dielectric and on the interface between the gate dielectric and the channel. The quality of this interface is critical to the reliability of the transistor, as changes at the interface can cause undesirable changes of the transistor performance characteristics, such as increased Vₜ and off current, and decreased saturated drain current and transconductance. These effects occur primarily on p-MOSFETS (equivalently known as p-channel MOSFETs), and are known as Negative Bias Temperature Instability, or NBTI.

NBTI is produced by thermal or voltage stress, but their combination is particularly effective in producing the effect. The activation temperature can be as low as 100° C., and the minimum necessary gate field strength is below 6 MV/cm. These are conditions routinely experienced by MOSFET transistors in current generation integrated circuits. The changes in transistor performance can significantly degrade circuit performance by causing changes in circuit timing, resulting in increased error rates or even device failure.

The root cause of NBTI is the formation of trapped charge at the interface between the gate oxide and the channel, which results from the removal of hydrogen at the interface between the channel and the gate dielectric. Hydrogen may be incorporated in the interface fortuitously as a result of hydrogen containing processes during fabrication, and is intentionally introduced at the end of the fabrication process with a forming gas anneal to passivate dangling bonds at the gate oxide-channel interface. These dangling bonds are a consequence of the lattice mismatch between crystalline silicon in the channel and amorphous silicon dioxide in the gate dielectric, and will result in trapped charge at the interface unless suitably passivated.

Several techniques to reduce NBTI are known, including fluorine implantation of the channel and modification of nitrogen content of nitrided gate oxide. Fluorine implantation, while effective at stabilizing the interface, introduces other detrimental effects, such as enhanced boron diffusion in the gate oxide and higher junction leakage. Reducing the nitrogen content of the gate also improves NBTI, but this must be weighed against the benefits of nitriding the gate, such as increased dielectric constant and reduction of boron diffusion through the gate dielectric.

Another method that is presently of intense focus within the semiconductor manufacturing industry involves the use of silicon nitride to incorporate hydrogen at the gate oxide interface. While silicon nitride does accomplish this purpose, the amount of free hydrogen that eventually gets incorporated is not sufficient to provide further reduction in NBTI drift.

Accordingly, what is needed in the art is a method of fabricating a semiconductor device that addresses these deficiencies.

### SUMMARY OF INVENTION

To overcome the deficiencies in the prior art, the invention, in one embodiment, provides a method of fabricating a semiconductor device. This embodiment comprises forming a hydrogen enriched carbide layer over a gate electrode and depositing a pre-metal dielectric layer over the carbide layer.

In another embodiment, the invention provides a semiconductor device that a semiconductor substrate, a gate electrode located over the semiconductor substrate, a carbide located layer over the gate electrode, and a pre-metal dielectric layer located over the carbide layer.

### BRIEF DESCRIPTION OF THE DRAWINGS

The invention is best understood from the following detailed description when read with the accompanying FIGUREs. Reference is now made to the following descriptions taken in conjunction with the accompanying drawings, in which:

FIG. 1 illustrates a sectional view of one embodiment of a semiconductor device provided by the invention;

FIGS. 2-5 illustrate various stages of manufacture of the semiconductor device; and

FIG. 6 illustrates a sectional view of an integrated circuit (IC) incorporating the semiconductor device.

### DETAILED DESCRIPTION

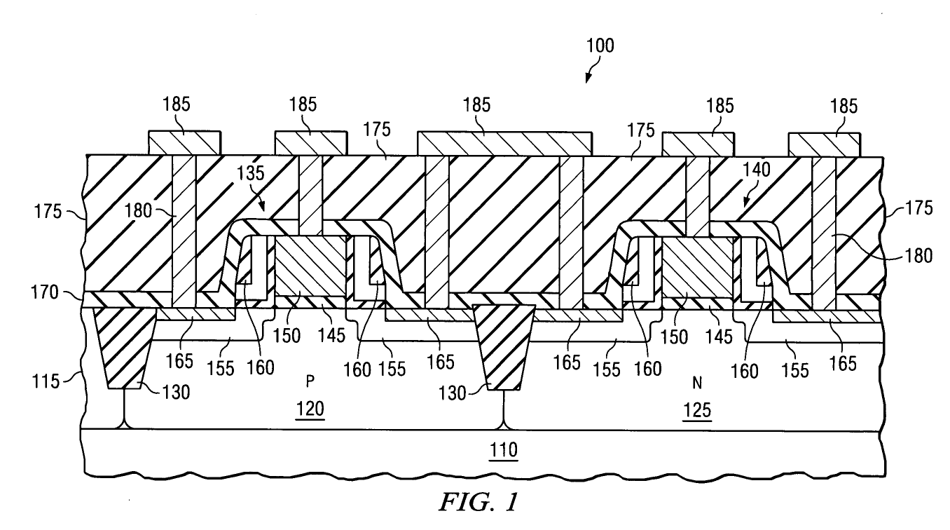

FIG. 1 is one embodiment of a semiconductor device 100 of the invention at one stage of manufacture. In this embodiment, the semiconductor device 100 comprises a semiconductor substrate 110. Located over the substrate 110 is an active region 115. Wells 120 and 125 are located in the active region 115. Isolation structures 130 are also located in the active region 115.

In the illustrated embodiment, the semiconductor device 100 includes transistors 135, 140. The transistor 135, 140 may also each comprise source/drains 155 and spacers 160. The semiconductor device 100 may further include silicide contacts 165.

The embodiment illustrated in FIG. 1 further includes a hydrogen enriched carbide layer 170 that is located over the gate electrodes 150. It has been found that the carbide layer 170 improves the NBTI of the semiconductor device 100 over those provided by conventional processes. In one aspect, the carbide layer 170 provides advantages over conventional layers, such as silicon nitride, by providing a smaller percentage of end of life (EOL) shift in the drive current of the semiconductor device 100. A reduction in EOL extends the devices useful life. Advantageously, the semiconductor device 100 experiences a reduction in the EOL shift in the drive current that is greater than about 5% when compared to a device that uses conventional materials instead of the carbide layer 170. A pre-metal dielectric (PMD) layer 175 is located over the carbide layer 170, and interconnects 180 and metal lines 185 are located within and over the PMD layer 175. Here the PMD layer 175 is the first dielectric layer in which interconnects 180 are formed and over which metal lines 185 are located.

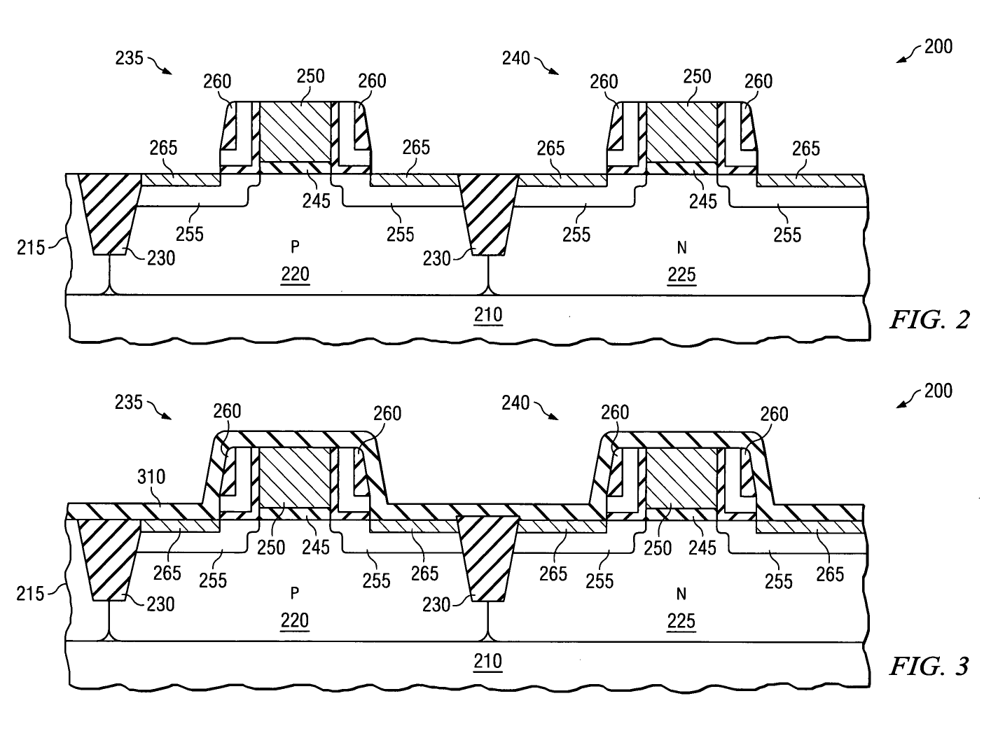

FIG. 2 shows an embodiment of a semiconductor device 200 of the invention in an early stage of manufacture. In this embodiment, the semiconductor device 200 includes the same features as discussed above and are numbered similarly. The substrate 210 may be a conventional semiconductor material, such as doped silicon, silicon germanium, gallium arsenide, or silicond-on-insulator (SOI) substrates. An active layer 215 is located over the substrate. The active layer 215 may be a portion of the substrate 210 that is doped to function as an active layer for the device 200, or it may be a conventionally doped epitaxial layer 210. Wells 220, 225 are located within the active layer 215, and they may be conventionally doped with the same type of dopant, or they may be complementary doped wells, as indicated. Isolation structures 230, such as isolation trenches, electrically isolate wells 220, 225 from each other. Conventional processes and materials may be used to construct these isolation structures 230.

The semiconductor device 200 may also include transistors 235, 240. The transistors 235, 240 may be configured as PMOS or NMOS, or they may be arranged in a complementary configuration, as shown. In certain embodiments, the transistors 235, 240, may comprise conventionally formed components, such as source/drains 255 and gate dielectric layers 245 over which are located gate electrodes 250. The gate electrodes 250 may also include conventionally formed spacers 260 that are located adjacent the gate electrodes 250. In some embodiments, the gate electrodes 250 may be doped polysilicon, silicided polysilicon, metal, or a combination of any of these. The source/drains 255 may include extension regions, such as lightly doped drains (LDDs) that extend under the spacers 260, but in other embodiments, the extension regions may not be present. The spacers 260 may comprise a single layer or multiple layers, as shown, and may be constructed with conventional materials, such as oxides, nitrides, or combinations thereof. At this stage of manufacture, silicide contacts 265, which may be fabricated using conventional processes and materials, have also been formed.

FIG. 3 illustrates the semiconductor device 200 following the deposition of a hydrogen enriched carbide layer 310 over the gate electrodes 250. The carbide layer 310 may be comprised of materials, such as silicon carbide nitride (SiCNH) or silicon carbide (SiCH). In one aspect, the carbide layer 310 has a general formula of SiCₓN_{y}H_{z}, wherein a value of x ranges from bout 10% to about 25% and a value of y ranges from about 0% to about 20%. The range of z depends on the deposition conditions, examples of which are discussed below.

The carbide layer 310 may be formed by using a gas mixture comprising carbon, silicon, and nitrogen, and deposition processes, such as plasma enhanced chemical vapor deposition (PECVD), atomic layer deposition (ALD), or spin on processes may be used. The gas mixture may vary and non-limiting examples of these gases include trimethyl silane or methyl silane, and ammonia. In one aspect, the flow rates of the gas mixture ranges from about 1200 sccm to about 3500 sccm, and in a more specific example, the flow rates of the hydrocarbon silane gas may range from about 200 sccm to about 500 sccm, while the flow rate of ammonia may range from about 0 sccm to about 1000 sccm, and the flow rate of carrier gas, such as helium, may range from about 1000 sccm to about 2000 sccm. Deposition temperatures may range from about 200° C. to about 400° C.

As initially deposited, the carbide layer 310 may contain varying amounts of hydrogen. For example, in one embodiment, the hydrogen enriched carbide layer 310 has the general formula of SiCₓN_{y}H_{z}, which in one example, the carbide layer contains an atomic amount of hydrogen wherein z ranges from about 30 atom percent to about 40 atom percent or higher. In a more specific embodiment, the atom percent of hydrogen may range from about 32 atom percent to about 38 atom percent. It should be understood that the above-discussed deposition parameters may be varied to achieve various hydrogen concentrations, as those stated above. The illustrated embodiment shows the carbide layer 310 located directly on the gate electrode 250. However, other embodiments include those where the carbide layer 310 is located over the gate electrodes 250 such that there may be intervening layers located between the gate electrodes 250 and the carbide layer 310 but prior to the first metal level. Moreover, it should be noted that the carbide layer 310 may also function as a contact etch stop layer for the gate electrodes 250 and as a PMD liner. Also, an added advantage is provided in that the contact etch selectivity of the carbide layer 310 to silicon dioxide can be slightly better than that of silicon nitride.

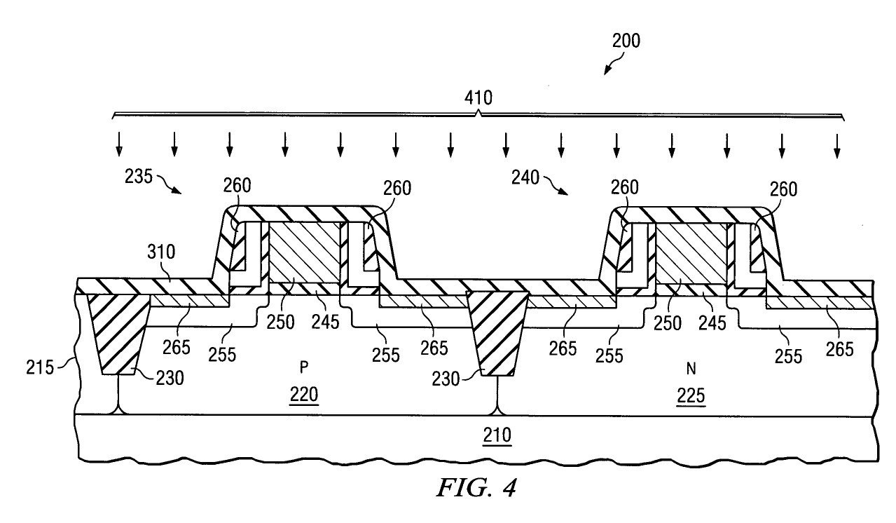

After its deposition, the hydrogen enriched carbide layer 310 is subjected to an anneal 410, as shown in FIG. 4. In one embodiment, the anneal 410 may be conducted at this point, or in another, the anneal 410 may be conducted following the deposition of a subsequent layer, such as a pre-metal dielectric layer. The type of anneal 410 that is conducted may vary depending on the embodiment. For example, in one embodiment, the anneal 410 may be a thermal anneal. In such embodiments, the anneal 410 may be conducted at a temperature that is greater than a deposition temperature of the carbide layer. In a more specific embodiment, the anneal 410 can be conducted at a temperature that ranges from about 200° C. to about 450° C. In such instances, the deposition temperature of the carbide layer may be less than about 400° C. These temperatures are illustrative only and other temperatures are within the scope of the invention. However, in those embodiments where silicided contacts are included, it is recommended that the temperatures that are used to conduct the anneal 410 be below the temperature that would cause the silicide to punch through the source/drain junction and cause leakage in the device.

In other embodiments, the anneal 410 may be conducted with ultra violet radiation, an electron beam, or a laser. These alternative processes can be particularly useful when lower anneal temperatures are required due to the materials present in the device. The laser can be pulsed within a few milliseconds to achieve a very high temperature sufficient to anneal the carbide layer 310, but still prevent further diffusion of the metals in the silicide contacts 265 due to the fact that the high temperature is brief enough such that further diffusion of the metal in the silicide does not occur. Following the anneal, the hydrogen content of the carbide layer 310 may decrease. For example, the atom percent of hydrogen in the carbide layer 310 may range from about 10% to about 25%.

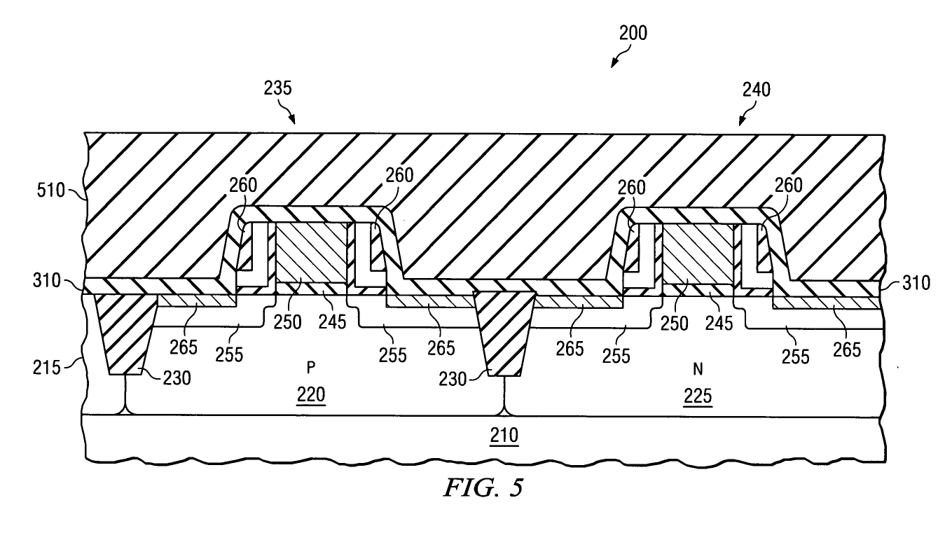

FIG. 5 shows the semiconductor device 200 following the deposition of a PMD layer 510 over the carbide layer 310. Depending on the manufacturer, what constitutes a PMD layer 510 may vary. What a PMD layer 510 means with respect to the invention is: any layer in which contact plugs are formed to contact the transistors 235 and 240 and on which a first interconnect metal layer is deposited. As mentioned above, in some instances the PMD layer 510 may be subjected to an anneal and in such instances the above-mentioned anneal 410 would occur at this point in the manufacturing process. The PMD layer 510 may be deposited using conventional materials and processes. Following the deposition and anneal, if applicable, of the PMD layer 510, conventional processes may be used to complete the semiconductor device 200 to form an operative integrated circuit (IC).

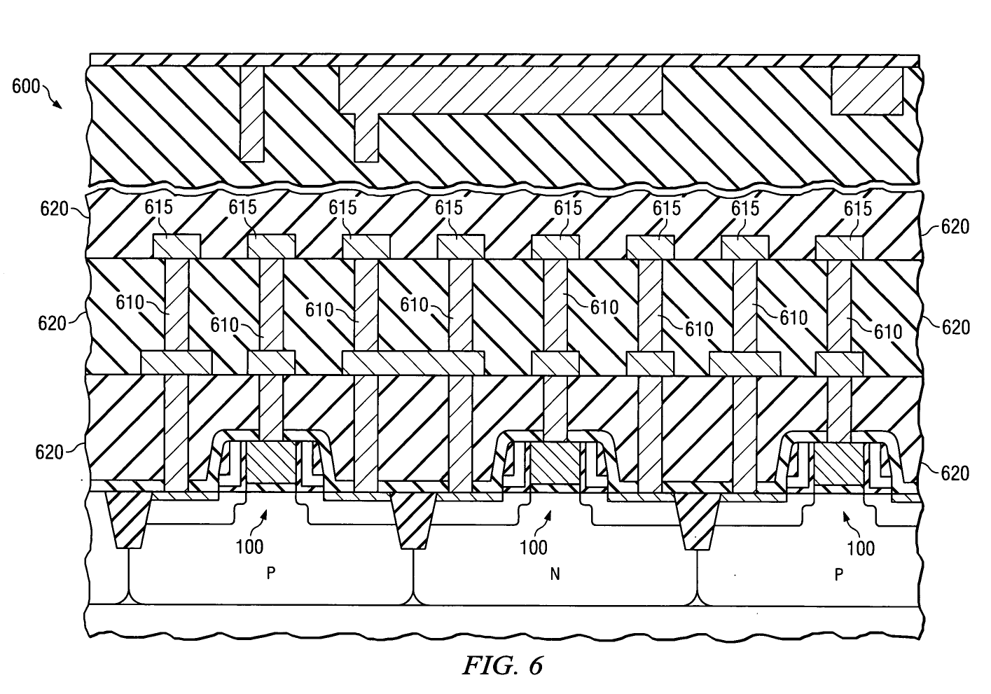

FIG. 6 is an IC 600 that incorporates the completed semiconductor device 100 of FIG. 1. The IC 600 may be configured into a wide variety of devices, as CMOS devices, BiCMOS devices, Bipolar devices, as well as capacitors or other types of devices. The IC 600 may further include passive devices, such as inductors or resistors, or it may also include optical devices or optoelectronic devices. The IC 600 includes the various components as discussed above, and conventional interconnect structures 610 and metal lines 615 electrically connect the components of the semiconductor device 100 to form an operative IC. The interconnect structures 610 and metal lines 615 may be formed in conventional dielectric layers 620 that are located over the semiconductor device 100. The number of dielectric layers 6320 and metal lines 615 will varying with design. Those skilled in the art are familiar with the process and materials that could be used to incorporate the semiconductor device 100 and arrive at the IC 600.

Those skilled in the art to which the invention relates will appreciate that other and further additions, deletions, substitutions, and modifications may be made to the described example embodiments, without departing from the invention.

What is claimed is:

1. A method of fabricating a semiconductor device, comprising:
forming a hydrogen enriched carbide layer over a gate electrode; and
depositing a pre-metal dielectric layer over the carbide layer.

2. The method recited in claim 1, wherein the hydrogen enriched carbide layer contains at least about 32 atom percent of hydrogen.

3. The method recited in claim 1, further including subjecting the hydrogen enriched carbide layer to an anneal, wherein the anneal is a thermal anneal conducted at a temperature that is greater than a deposition temperature of the hydrogen enriched carbide layer.

4. The method recited in claim 3, wherein the thermal anneal is conducted at a temperature that ranges from about 200° C. to about 450° C. and the deposition temperature is less than about 400° C.

5. The method recited in claim 3, wherein the anneal is conducted with ultra violet radiation, an electron beam, or a laser.

6. The method recited in claim 3, wherein the anneal is conducted subsequent to depositing the pre-metal dielectric layer.

7. The method recited in claim 1, wherein forming the hydrogen enriched carbide layer includes using a gas mixture comprising carbon, silicon, and nitrogen.

8. The method recited in claim 7, wherein the gas mixture comprises trimethyl silane or methyl silane, and ammonia.

9. The method recited in claim 1, wherein the hydrogen enriched carbide layer has a general formula of SiCₓN_{y}H_{z}, wherein a value of x ranges from bout 10% to about 25%, a value of y ranges from about 0% to about 20%, and a value of z ranges from about 10% to about 25%

10. The method recited in claim 1, further comprising forming a plurality of gate electrodes, forming interlevel dielectric layers over the gate electrodes, forming interconnects in the interlevel dielectric layers that interconnect the gate electrodes to form an operative integrated circuit.

11. The method recited in claim 1 wherein forming the carbide layer includes depositing the carbide layer by plasma enhanced chemical vapor deposition, atomic layer deposition, or by spin on processes.

12. The method recited in claim 11 wherein a deposition temperature ranges from about 200° C. to about 400° C.

13. A semiconductor device, comprising:
a semiconductor substrate;
a gate electrode located over the semiconductor substrate;
a carbide located layer over the gate electrode; and
a pre-metal dielectric layer located over the carbide layer.

14. The semiconductor device recited in claim 13, wherein the carbide layer contains an atom percent of hydrogen ranging from about 10% to about 25%.

15. The semiconductor device recited in claim 13, wherein the semiconductor device has an end of life shift in the drive current that is less than about 15%.

16. The semiconductor device recited in claim 13, wherein the carbide layer comprises silicon carbide nitride or silicon carbide and has a general formula of SiCₓN_{y}H_{z}, wherein a value of x ranges from bout 10% to about 25%, a value of y ranges from about 0% to about 20%, and a value of z ranges from about 10% to about 25%.

17. The semiconductor device recited in claim 16, wherein the carbide layer is silicon carbide nitride (SiCNH) or silicon carbide (SiCH).

18. The semiconductor device recited in claim 13, wherein the carbide layer is located on the gate electrode and is a contact etch stop layer for the gate electrode.

19. The semiconductor device recited in claim 13, wherein the semiconductor device is an integrated circuit that further comprises:
transistors located over or within the semiconductor substrate and that each includes the gate electrode;
dielectric layers located over the transistors; and
interconnects located within the dielectric layers that electrically interconnect the transistors to form an operative integrated circuit.

20. The semiconductor device as recited in claim 13 further comprising silicided contacts located adjacent the gate electrode.
